(19) United States
(12) Patent Application Publication
(10) Pub. No.: US 2012/0105129 A1
(43) Pub. Date: May 3, 2012

(54) APPARATUS FOR MONOLITHIC POWER GATING ON AN INTEGRATED CIRCUIT

(76) Inventors: Samuel D. Naffziger, Fort Collins, CO (US); Bruce Gieseke, San Jose, CA (US); Benjamin Beker, Spicewood, TX (US)

(21) Appl. No.: 12/914,110

(22) Filed: Oct. 28, 2010

(51) Int. Cl. H03K 17/56

(52) U.S. Cl. 327/419

(57) ABSTRACT

A power gating apparatus includes an integrated circuit package with a first voltage reference plane and a second voltage reference plane, and an integrated circuit that includes a circuit block, and a switch block. The first and second voltage reference planes may be electrically isolated from one another. The switch block may include a plurality of switches arranged in a ring surrounding the circuit block. The first voltage reference plane may be electrically coupled between an external voltage reference and the plurality of switches, and the second voltage reference plane may be electrically coupled between the plurality of switches and the circuit block. The second voltage reference plane may also distribute an electric current throughout the circuit block. In addition, each of the switches is configured to interrupt an electrical path between the first reference voltage plane and the circuit block in response to a control signal.

### BACKGROUND

1. Technical Field

This disclosure relates to integrated circuits and, more particularly, to a power gating mechanism on the integrated circuits.

2. Description of the Related Art

Electronic devices and particularly those with modern processors are capable of consuming a great deal of power. In an effort to conserve battery life, in many systems it is becoming commonplace to turn off components that are not being used. Power gating, which is the term used to describe completely removing the voltage reference or the circuit ground reference from the component, is being widely used. This is in contrast to simply stopping the clock on a processor, for example. However, although power gating may be one of the most effective ways to reduce power consumption of a component, conventional power gating has some drawbacks.

One such drawback is the necessity of instantiating power gating transistors into the logic portion of the component. In many cases these power gating transistors are distributed throughout the logic of the component. Another drawback is the use of abnormally thick (and expensive) on-die metallization to redistribute current from the distant distributed power gate devices to the power consuming circuitry.

### SUMMARY OF THE EMBODIMENTS

Various embodiments of an apparatus for power gating on an integrated circuit are disclosed. In one embodiment, the apparatus includes an integrated circuit package with a first voltage reference plane and a second voltage reference plane, and an integrated circuit that includes a circuit block such as a processor core, for example, and a switch block. The first and second voltage reference planes may be electrically isolated from one another. The switch block may include a plurality of switches arranged in a ring surrounding the circuit block. The first voltage reference plane may be electrically coupled between an external voltage reference such as VSS, for example, and the plurality of switches, and the second voltage reference plane may be electrically coupled between the plurality of switches and the circuit block. The second voltage reference plane may also be configured to distribute an electric current throughout the circuit block. In addition, each of the switches is configured to interrupt an electrical path between the first reference voltage plane and the circuit block in response to a control signal.

### BRIEF DESCRIPTION OF THE DRAWINGS

FIG. 1 is a top view diagram of a floorplan one embodiment of an integrated circuit (IC) including a power gate ring and core logic.

FIG. 2 is a side view of an IC package, which includes isolated reference planes, mated to an IC die that includes a power gating ring.

FIG. 3 is a perspective view drawing illustrating additional details of an embodiment of the IC package reference planes of FIG. 2.

FIG. 4 is a top view diagram of the floorplan of one embodiment of a processing node including multiple processor cores and power gating rings.

Specific embodiments are shown by way of example in the drawings and will herein be described in detail. It should be understood, however, that the drawings and detailed description are not intended to limit the claims to the particular embodiments disclosed, even where only a single embodiment is described with respect to a particular feature. On the contrary, the intention is to cover all modifications, equivalents and alternatives that would be apparent to a person skilled in the art having the benefit of this disclosure. Examples of features provided in the disclosure are intended to be illustrative rather than restrictive unless stated otherwise.

As used throughout this application, the word “may” is used in a permissive sense (i.e., meaning having the potential to), rather than the mandatory sense (i.e., meaning must). Similarly, the words “include,” “including,” and “includes” mean including, but not limited to.

Various units, circuits, or other components may be described as “configured to” perform a task or tasks. In such contexts, “configured to” is a broad recitation of structure generally meaning “having circuitry that” performs the task or tasks during operation. As such, the unit/circuit/component can be configured to perform the task even when the unit/circuit/component is not currently on. In general, the circuitry that forms the structure corresponding to “configured to” may include hardware circuits. Similarly, various units/circuits/components may be described as performing a task or tasks, for convenience in the description. Such descriptions should be interpreted as including the phrase “configured to.” Reciting a unit/circuit/component that is configured to perform one or more tasks is expressly intended not to invoke 35 U.S.C. §112, paragraph six, interpretation for that unit/circuit/component.

### DETAILED DESCRIPTION OF EMBODIMENTS

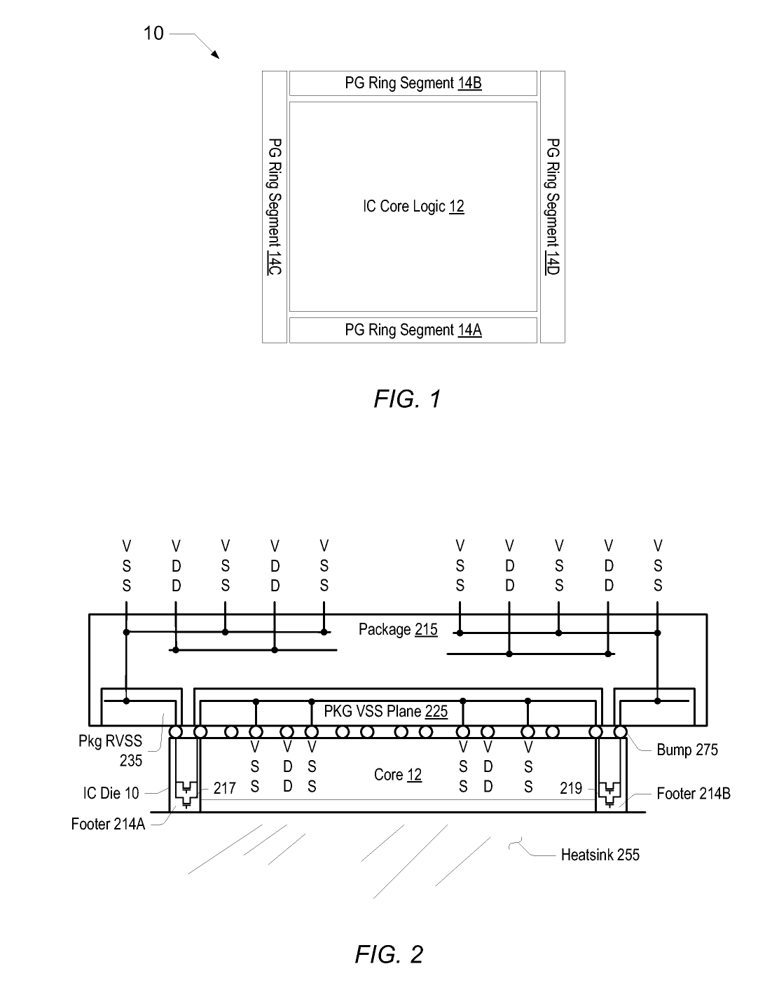

Turning now to FIG. 1, a top view diagram depicting a floorplan of one embodiment of an integrated circuit (IC) die including a power gating ring is shown. The IC 10 includes semiconductor substrate (not shown in FIG. 1) upon which a core logic section or block 12, and several power gating ring segments, designated PG Ring segments 14A through 14D, have been formed. It is noted that although four separate PG ring segments are shown, there may be a single contiguous PG ring in other embodiments. It is also noted that components having a reference designator with a number and a letter may be referred to using the number only where appropriate.

As will be described in greater detail below, the PG ring segments 14 may include a plurality of switches (e.g., transistors) that may be coupled between the circuit ground reference (VSS) and/or the voltage reference/supply voltage (VDD) supplied through an IC package (not shown) and the VSS or the VDD connections on the IC core logic portion 12. As shown, the PG ring segments 14 are arranged around the periphery of the IC core logic 12, and are thus not part of the IC core logic 12.

In one embodiment, the PG ring segments 14 may be controlled by control logic that may be employed outside of the PG ring segments 14. For example, if the IC core logic 12 and the PG ring segments 14 are part of a larger IC 10 having additional components such as in a system on a chip (SOC), the SOC may include the control logic that causes the switches in the PG ring segments 14 to turn on and off.

It is noted that the IC core logic 12 may be representative of any type integrated circuit logic. More particularly, it is contemplated that the IC core logic 12 may be any logic block that may need to be powered on and off independent of other logic blocks, and/or other circuit components.

Referring to FIG. 2, a side view of one embodiment of an IC package, which includes isolated reference planes, mated to an IC die that includes an embodiment of the power gating ring of FIG. 1 is shown. The IC package 215 is mechanically and electrically coupled to the IC die 10 by the bumps 275.

As described above in conjunction with the description of FIG. 1, the IC die 10 includes a substrate which is used to form the components that make up the core section 12, and the footer sections 214A and 214B. More particularly, in one embodiment the footer sections include a plurality of transistors (e.g., switches) such as transistors 217 and 219, for example. In addition, the IC die 10 includes several connections for VSS and VDD.

Many IC packages include one or more voltage reference planes that are used to distribute VDD and VSS across an IC die such as IC die 10. Accordingly, as shown in FIG. 2, the IC package 215 includes a package RVSS plane 235 and a package VSS plane 225. In one embodiment, the package 215 includes external connections for the circuit ground reference (VSS) and the voltage reference or supply voltage (VDD). These voltage and ground references may be provided to the package 215 through a motherboard and power supply/voltage regulator arrangement (not shown).

In the illustrated embodiment the external VSS connections are coupled together and to the Pkg RVSS plane 235. This provides an external distribution path for VSS within a portion of the package 215. In addition, the connections in the Pkg VSS plane 225 are coupled together and to the core logic 12 of the IC die 10 when the package 215 is bonded to the IC die 10. Thus, the Pkg VSS plane 225 provides a distribution path for the VSS current on the IC die 10 in the other portion of the package 215. However, as shown, the Pkg RVSS plane 235 and the Pkg VSS plane 225 are electrically isolated from one another. Accordingly, the transistors 217 and 219, when conducting, provide a VSS path between the Pkg RVSS plane 235 and the Pkg VSS plane 225. Thus, in one embodiment, when it is desirable to power off the IC die 10, the transistors 217 and 219 may be turned off through control signals (not shown) provided external to the footers 214 and the core 12.

It is noted that although FIG. 2 and its corresponding description, detail the switching and distribution of VSS, it is contemplated that in other embodiments, the Pkg VDD planes may be used in a similar way to the Pkg VSS plane, and the transistors 217 and 219 could switch VDD instead of VSS, as desired. However, in such embodiments, rather than the transistors 217 and 219 residing in a footer, the transistors 217 and 219 would be implemented in a header region (not shown). It is noted that the VDD connections to the IC die 10 and in the Pkg VDD plane are not shown for simplicity.

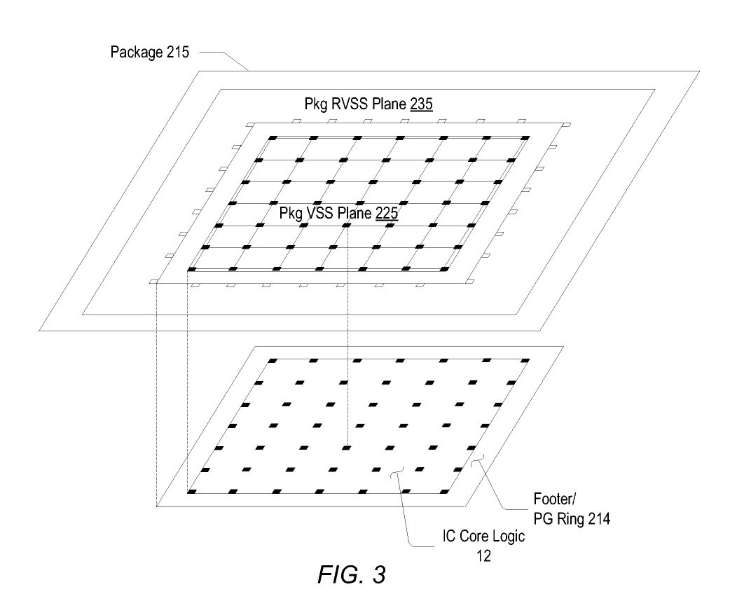

Turning to FIG. 3, a perspective view drawing illustrating additional details of an embodiment of the IC package reference planes of FIG. 2 is shown. As shown in FIG. 2, the IC package 215 of FIG. 3 includes a Pkg RVSS plane 235 and a Pkg VSS plane 225. As shown, the Pkg RVSS plane 235 has a number of VSS connections around the periphery of the rectangle, which forms the periphery of the footer/PG ring 214. The Pkg VSS 225 plane also has a number of connections distributed across the plane for connection to the IC core logic 12. In addition, the connections on the Pkg VSS plane 225 are coupled together to form a current distribution grid.

As shown, the Pkg RVSS plane 235 and a Pkg VSS plane 225 are not electrically connected in the package. Accordingly, as described above in conjunction with the description of FIG. 2, the transistors in the footer/power gate ring 214 provide the connectivity between the two VSS planes, while the Pkg VSS plane 225 forms a current distribution grid for the core logic 12. Thus, the combination may provide a relatively inexpensive power gating solution. It is noted that the drawings in FIG. 3 are not to scale and that the footer/power gate ring 214 is shown exploded for illustrative purposes.

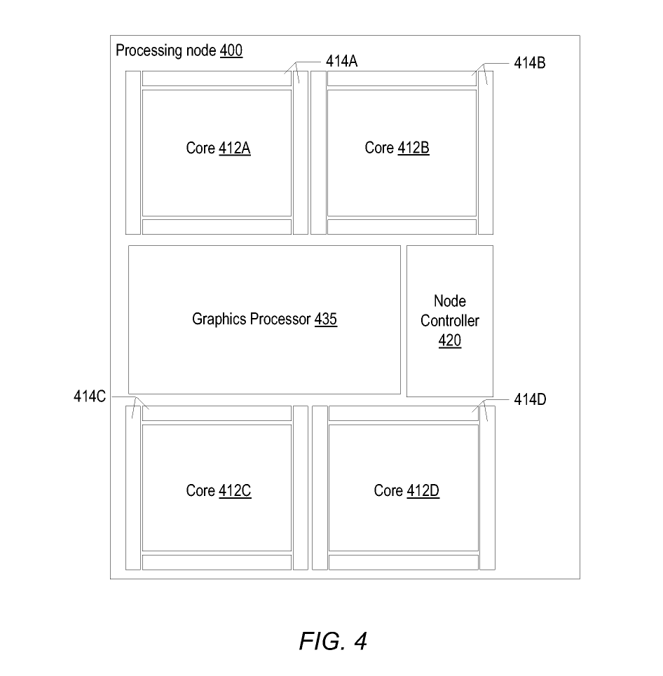

Referring to FIG. 4, a top view diagram of the floorplan of one embodiment of a processing node is shown. In the illustrated embodiment, the processing node 400 includes processor cores 412A-412D, a node controller 420, and a graphics processor 435. As shown, each of the processor cores 412A-412D is surrounded by a power gating ring 414A-414D, respectively. In one embodiment, each of the power gating rings 414 may be representative of the power gating rings 14 shown in FIGS. 1, and 214 in FIG. 2 and FIG. 3. As such, in one embodiment, each of the power gating rings 414 may include multiple segments, although other embodiments may include a single power gating ring structure. In one embodiment, node 400 may be a single integrated circuit chip comprising the circuitry shown therein in FIG. 1. That is, node 400 may be a system on a chip (SOC) or a chip multiprocessor (CMP). Processor cores 412A-412D may be any type of processing element and may not be identical nor even similar to each other. For example, processor core 412A-412D may be representative of a central processing unit (CPU) core, digital signal processing (DSP) core, application processor (AP) core or any other core. Additionally, processor cores 412A-412D may be any combinations thereof.

It is also noted that, a processing node such as node 400 may include any number of processor cores, in various embodiments. It is further noted that processor node 400 may include many other components that have been omitted here for simplicity. For example, in various embodiments processing node 400 may include an integral memory controller and various communication interfaces for communicating with other nodes, and I/O devices.

In one embodiment, node controller 420 may include various interconnection circuits (not shown) for interconnecting processor cores 412A-41D to each other, to other nodes, and to a system memory (not shown).

As described above, the power gating rings 414 may be used to independently power on and off the processor cores 412. Accordingly, in one embodiment, the node controller 420 may also include logic to control the power gating rings 414, and thus to power on and off the individual processor cores 412.

Thus, the above embodiments may provide a mechanism that enables low cost power gating of small or large complex IP (such as processor cores—e.g., central processing cores, graphics cores, digital signal processing cores, etc.) with a relatively simple design process (the power gating ring), and no additional costs in either on-die metal layers, or additional package layers since the existing package power/ground planes may be simply subdivided into gated (e.g., 225) and non-gated (e.g., 235) regions.

Although the embodiments above have been described in considerable detail, numerous variations and modifications will become apparent to those skilled in the art once the above disclosure is fully appreciated. It is intended that the following claims be interpreted to embrace all such variations and modifications.

What is claimed is:

1. An apparatus comprising:
an integrated circuit package including a first voltage reference plane and a second voltage reference plane, wherein the first and second voltage reference planes are electrically isolated from one another; and
an integrated circuit die including:
a circuit block; and
a switch block including a plurality of switches arranged in a ring surrounding the circuit block;
wherein the first voltage reference plane is electrically coupled between an external voltage reference and the plurality of switches, and the second voltage reference plane is electrically coupled between the plurality of switches and the circuit block, wherein the second voltage reference plane is configured to distribute an electric current throughout the circuit block; and
wherein each of the switches is configured to interrupt an electrical path between the first reference voltage plane and the circuit block in response to a control signal.

2. The apparatus as recited in claim 1, wherein the switch block includes a plurality of connection nodes, wherein a first portion of the plurality of connection nodes is electrically coupled to the first voltage reference plane, and a second portion of the plurality of connection nodes is electrically coupled to the second voltage reference plane.

3. The apparatus as recited in claim 1, wherein the external voltage reference is VSS.

4. The apparatus as recited in claim 1, wherein the external voltage reference is VDD.

5. The apparatus as recited in claim 1, wherein the second reference voltage plane comprises a conductive grid including a plurality of connection nodes for connection to corresponding connection nodes formed within the circuit block.

6. The apparatus as recited in claim 1, wherein the first reference voltage plane comprises a conductive grid including a plurality of connection nodes for connection to a plurality of connections external to the integrated circuit package.

7. The apparatus as recited in claim 3, wherein the plurality of switches comprises a plurality of transistors formed in a footer, wherein the footer is coupled to the first and second voltage reference planes through a plurality of metal layers of the integrated circuit.

8. The apparatus as recited in claim 4, wherein the plurality of switches comprises a plurality of transistors formed in a header, wherein the header is coupled to the first and second voltage reference planes through one or more metal layers of the integrated circuit.

9. A system comprising:
an integrated circuit package including a first voltage reference plane and a plurality of second voltage reference planes, wherein the first voltage reference plane and each of the second voltage reference planes are electrically isolated from one another; and
a processing node including:
a plurality of processor cores; and
a plurality of switch blocks, each switch block including a plurality of switches arranged in a ring around a respective corresponding processor core;
wherein the first voltage reference plane is electrically coupled between an external voltage reference and the plurality of switch blocks, and each of the second voltage reference planes is electrically coupled between a separate switch block and the respective corresponding processor core, wherein each of the second voltage reference planes is configured to distribute an electric current throughout the respective corresponding processor core; and
wherein each of the switches in a given switch block is configured to interrupt an electrical path between the first reference voltage plane and the respective corresponding processor core in response to a control signal.

10. The system as recited in claim 9, wherein each switch block includes a plurality of connection nodes, wherein a first portion of the plurality of connection nodes is electrically coupled to the first voltage reference plane, and a second portion of the plurality of connection nodes is electrically coupled to the second voltage reference plane.

11. The system as recited in claim 9, wherein the external voltage reference is VSS.

12. The system as recited in claim 9, wherein the external voltage reference is VDD.

13. The system as recited in claim 9, wherein each second reference voltage plane comprises a conductive grid including a plurality of connection nodes for connection to corresponding connection nodes formed within each respective corresponding processor core.

14. The system as recited in claim 9, wherein the first reference voltage plane comprises a conductive grid including a plurality of connection nodes for connection to a plurality of connections external to the integrated circuit package.

15. The system as recited in claim 11, wherein the plurality of switches comprises a plurality of transistors formed in a footer of an integrated circuit upon which the processing node is fabricated, wherein the footer is coupled to the first and second voltage reference planes through a plurality of metal layers of the integrated circuit.

16. The system as recited in claim 12, wherein the plurality of switches comprises a plurality of transistors formed in a header of an integrated circuit upon which the processing node is fabricated, wherein the header is coupled to the first and second voltage reference planes through one or more metal layers of the integrated circuit.

17. A method comprising:
electrically bonding an integrated circuit package including a first voltage reference plane and a second voltage reference plane to an integrated circuit die including a circuit block, and a switch block including a plurality of switches arranged in a ring surrounding the circuit block;
wherein the first and second voltage reference planes are electrically isolated from one another;
electrically coupling the first voltage reference plane between an external voltage reference connection and the plurality of switches, and electrically coupling the second voltage reference plane between the plurality of switches and the circuit block.

18. The method as recited in claim 17, further comprising electrically coupling a first portion of a plurality of connection nodes of the switch block to the first voltage reference plane, and electrically coupling a second portion of the plurality of connection nodes to the second voltage reference plane.

19. The method as recited in claim 17, further comprising electrically coupling a conductive grid including a plurality of connection nodes of the second reference voltage plane to corresponding connection nodes within the circuit block.

20. The method as recited in claim 17, further comprising electrically coupling a conductive grid including a plurality of connection nodes of the first reference voltage plane to a plurality of connections external to the integrated circuit package.
